(19) United States
(12) Patent Application Publication
(10) Pub. No.: US 2022/0137500 A1
(43) Pub. Date: May 5, 2022

(54) GLASS SUBSTRATE FOR EUVL, AND MASK BLANK FOR EUVL

(71) Applicant: AGC Inc., Tokyo (JP)

(72) Inventors: Daisuke YOSHIMUNE, Fukushima (JP); Masahiko TAMURA, Fukushima (JP)

(73) Assignee: AGC Inc., Tokyo (JP)

(21) Appl. No.: 17/501,239

(22) Filed: Oct. 14, 2021

(30) Foreign Application Priority Data
Oct. 30, 2020 (JP) 2020-182453
Aug. 26, 2021 (JP) 2021-138312

(51) Int. Cl. G03F 1/24; G03F 1/58; H01L 21/033

(52) U.S. Cl. CPC G03F 1/24; H01L 21/0332; H01L 21/0337; G03F 1/58

(57) ABSTRACT

A glass substrate for EUVL has a rectangular first main surface on which a conductive film is formed and a rectangular second main surface, facing in a direction opposite to a direction in which the first main surface faces, on which an EUV reflective film and an EUV absorbing film are formed in a stated order. When coordinates of points of a central area of the first main surface excluding a rectangular frame-like peripheral area, the first main surface having a square shape of 142 mm in vertical direction and 142 mm in a horizontal direction, are expressed by (x, y, z(x,y)), a maximum height difference of a surface that is a set of coordinates (x, y, z3(x,y)) calculated by using Formula (1)-(3) is 6.0 nm or less.

### CROSS-REFERENCE TO RELATED APPLICATIONS

The present application is based on and claims benefit of priority under 35 U.S.C. § 119 of Japanese Patent Applications No. 2020-182453, filed Oct. 30, 2020, and No. 2021-138312, filed Aug. 26, 2021. The contents of these applications are incorporated herein by reference in their entirety.

### BACKGROUND OF THE INVENTION

### 1. Field of the Invention

The present invention relates to a glass substrate for extreme ultra-violet lithography (EUVL), and a mask blank for EUVL.

### 2. Description of the Related Art

In the related art, a photolithographic technique is used to fabricate semiconductor devices. In the photolithography technique, an exposure apparatus illuminates a circuit pattern of a photomask with light and transfers the circuit pattern to a resist film in a reduced size.

Recently, the use of short-wavelength exposure light, such as ArF excimer laser light, and even extreme ultra-violet (EUV) light, is studied to enable transfer of a fine circuit pattern.

Extreme UV (EUV) light refers to light that includes soft X-rays and vacuum UV rays, specifically having a wavelength of about 0.2 nm through 100 nm. At present, EUV light of wavelengths of about 13.5 nm is mainly studied.

A photomask for EUVL is obtained by forming a circuit pattern in a mask blank for EUVL.

A mask blank for EUVL has a glass substrate, a conductive film formed on a first main surface of the glass substrate, an EUV reflective film formed on a second main surface of the glass substrate, and an EUV absorbing film. The EUV reflective film and the EUV absorbing film are formed in the stated order.

The EUV reflective film reflects EUV light. The EUV absorbing film absorbs EUV light. A circuit pattern that is an opening pattern, is formed onto the EUV absorbing film. The conductive film is attracted by an electrostatic chuck of an exposure apparatus.

A mask blank for EUVL is to have high flatness to improve transfer accuracy of a circuit pattern. Flatness mainly depends on flatness of a glass substrate for EUVL. Therefore, a glass substrate for EUVL is to have high flatness also.

A mask blank for EUVL disclosed in Japanese Patent No. 6229807 has a central area and a peripheral area on a main surface of a conductive film opposite to a glass substrate. The central area is a square area of 142 mm in a vertical direction and 142 mm in a horizontal direction, excluding the peripheral area like a rectangular frame around the central area. The central area is 20 nm or less in flatness with respect to components whose orders with respect to a Legendre polynomial are 3 or more and 25 or less.

A mask blank for EUVL disclosed in U.S. Pat. No. 6,033,987 has a difference between a maximum height and a minimum height within an area, for which difference data between a composite surface shape and a virtual surface shape is calculated, is 25 nm or less. The area for which the difference data between the composite surface shape and the virtual surface shape is calculated is an inner area of a 104 mm diameter circle. The composite surface shape is obtained from combining a surface shape of a multilayered reflective film and a surface shape of a conductive film. The virtual surface shape is defined by a Zernike polynomial expressed according to a polar coordinate system.

### SUMMARY OF THE INVENTION

As described above, a glass substrate for EUVL is to have high flatness. Therefore, a central area of a main surface of a glass substrate for EUVL is typically subjected to polishing, local machining, and final polishing in the stated order. A specific method of local machining may be, for example, gas cluster ion beam (GCIB) or plasma chemical vaporization machining (PCVM).

In final polishing, a glass substrate for EUVL is pressed against a platen while the glass substrate for EUVL and the platen are being rotated. A central area of a main surface of the glass substrate for EUVL undergoes final polishing axisymmetrically with respect to its center, but does not undergo final polishing completely axisymmetrically. As a result, axisymmetric components and remaining distortion components are included after the final polishing.

The distortion components include fourfold rotationally symmetric components with respect to rotation about a center of the central area. The fourfold rotationally symmetric components are produced through the final polishing. The fourfold rotationally symmetric components are preferably expressed by a Zernike polynomial rather than a Legendre polynomial. A Zernike polynomial, unlike a Legendre polynomial, is expressed by polar coordinates and is suitable for removing axisymmetric components.

A shape that is fourfold rotationally symmetric with respect to rotation about a point is a shape which, after being rotated about the point by an angle of 90°, looks exactly the same as the original shape.

However, unlike a Legendre polynomial, a Zernike polynomial can express only a circular area. A main surface of a glass substrate for EUVL is rectangular, its central area is rectangular, and four corners of a rectangle cannot be expressed by a Zernike polynomial. Accordingly, in the related art, distortion components produced through final polishing cannot be accurately identified.

As a result, in the related art, it is difficult to control flatness of a central area of a main surface of a glass substrate for EUVL such that the flatness is less than 10.0 nm.

One aspect of the present invention provides a technique for controlling flatness of a central area of a main surface of a glass substrate for EUVL such that the flatness is less than 10.0 nm.

In accordance with the aspect of the present invention, a glass substrate for EUVL includes a first main surface rectangular in shape, on which a conductive film is formed; and a second main surface rectangular in shape, on which an EUV reflective film and an EUV absorbing film are formed in a stated order, the second main surface facing in a direction opposite to a direction in which the first main surface faces. When coordinates of a central area of the first main surface excluding a rectangular frame-like peripheral, the central area having a square shape of 142 mm in a vertical direction and 142 mm in a horizontal direction, are expressed by (x, y, z(x,y)), a maximum height difference of a surface that is a set of coordinates (x, y, z3(x,y)) calculated using following Formulas (1) through (3) is 6.0 nm or less.

$$\{ \begin{matrix}z 1 ( x , y ) = \{ z ( x , y ) + z ( y , - x ) + z ( - x , - y ) + z ( - y , x ) \} / 4 \\ z 2 ( x , y ) = \{ \begin{matrix}z ( x , y ) + z ( y , x ) + z ( y , - x ) + z ( x , - y ) + \\ z ( - x , - y ) + z ( - y , - x ) + z ( - y , x ) + z ( - x , y )\end{matrix} \} / 8 \\ z 3 ( x , y ) = z 1 ( x , y ) - z 2 ( x , y )\end{matrix} \qquad \begin{matrix}\begin{matrix}( 1 ) \\ ( 2 )\end{matrix} \\ \\ ( 3 )\end{matrix}$$

In the above-described coordinates (x, y, z(x,y)), x denotes a coordinate with respect to the horizontal direction, y denotes a coordinate with respect to the vertical direction, and z denotes a coordinate with respect to a height direction; and the horizontal direction, the vertical direction, and the height direction are perpendicular to one another.

As a result, flatness of the central area of the main surface of the glass substrate for EUVL can be controlled such that the flatness is less than 10.0 nm.

### BRIEF DESCRIPTION OF THE DRAWINGS

Other objects and further features of embodiments will become apparent from the following detailed description when read in conjunction with the accompanying drawings, in which:

FIG. 1 is a flowchart depicting a method for manufacturing a mask blank for EUVL according to an embodiment;

FIG. 2 is a cross-sectional view depicting a glass substrate for EUVL according to the embodiment;

FIG. 3 is a plan view depicting the glass substrate for EUVL according to the embodiment;

FIG. 4 is a cross-sectional view depicting the mask blank for EUVL according to the embodiment;

FIG. 5 is a cross-sectional view depicting an example of a photomask for EUVL;

FIG. 6 is a perspective view depicting an example of a double-side polishing machine in which a part of the double-side polishing machine is cut away;

FIG. 7 is a diagram depicting an example of a height distribution with respect to a central area of a first main surface after final polishing;

FIG. 8 is a plan view depicting an example of an arrangement of multiple points that are set on the central area;

FIG. 9 is a diagram depicting a height distribution with respect to components extracted using Formula (1) from the height distribution depicted in FIG. 7;

FIG. 10 is a diagram depicting a height distribution with respect to components extracted using Formula (2) from the height distribution depicted in FIG. 7;

FIG. 11 is a diagram depicting a height distribution with respect to components extracted using Formula (3) from the height distribution depicted in FIG. 7; and

FIG. 12 is a plan view depicting a relative rotational direction of a platen relative to the central area.

### DETAILED DESCRIPTION OF THE PREFERRED EMBODIMENTS

Hereinafter, embodiments of the present invention will be described with reference to the drawings. In each drawing, the same or corresponding elements are indicated by the same reference numerals and the description may be omitted. In the description, a word “through” indicating a numerical range means that the numerical range includes the numerical values mentioned before and after the word as the lower limit value and the upper limit value.

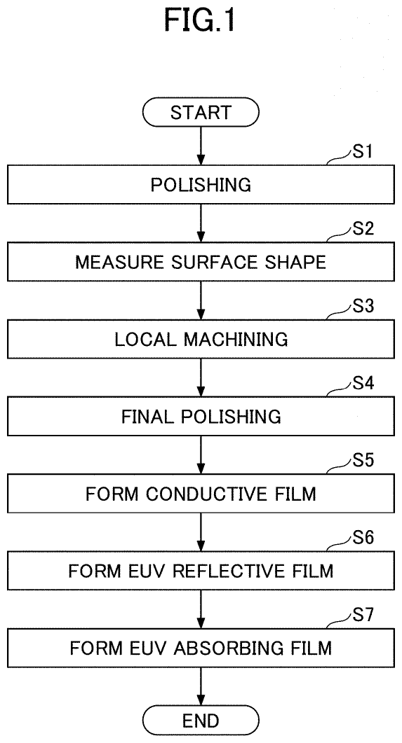

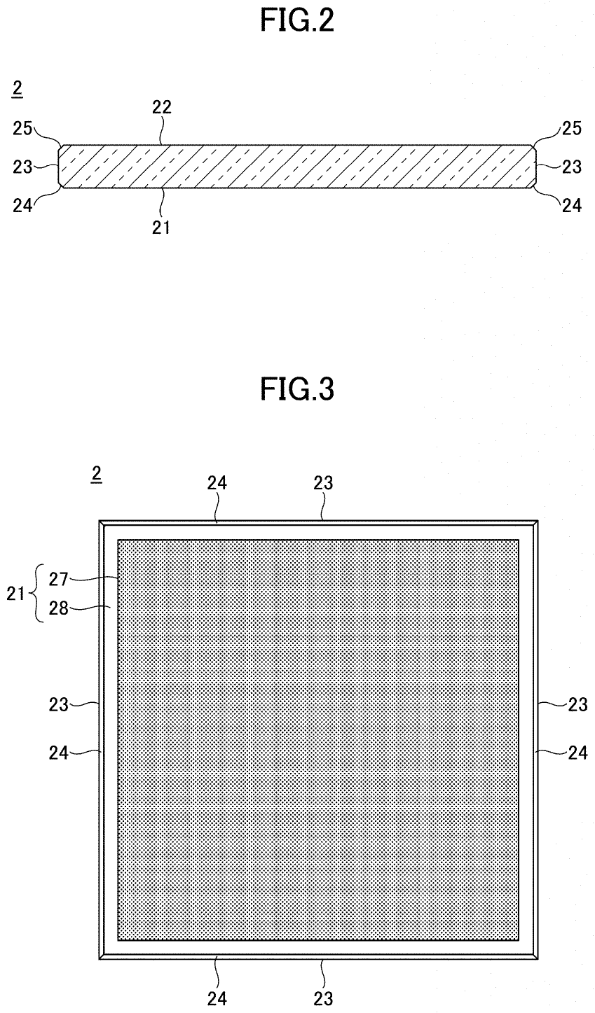

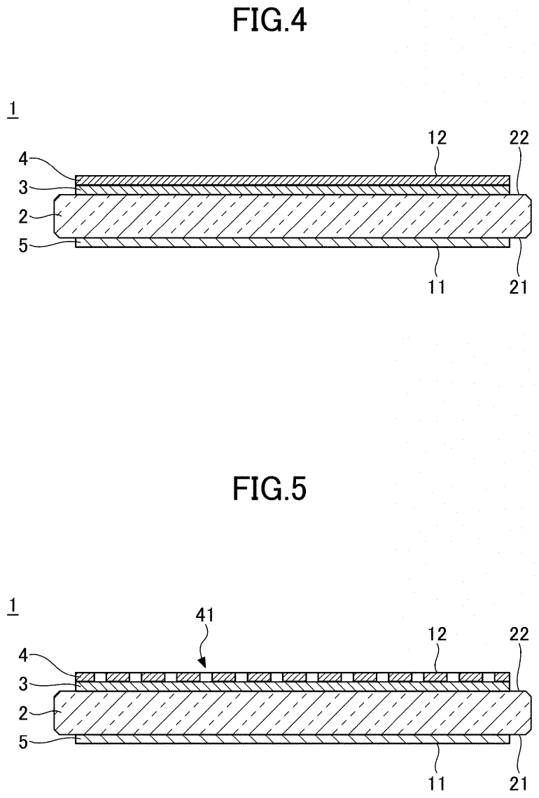

As depicted in FIG. 1, a method of manufacturing a mask blank for EUVL includes steps S1-S7. The mask blank 1 for EUVL depicted in FIG. 4 is manufactured using a glass substrate 2 for EUVL depicted in FIGS. 2 and 3. Hereinafter, the mask blank 1 for EUVL is also simply referred to as a mask blank 1. The glass substrate 2 for EUVL is also simply referred to as a glass substrate 2.

The glass substrate 2 includes a first main surface 21 and a second main surface 22 facing in a direction opposite to a direction in which the first main surface 21 faces, as depicted in FIGS. 2 and 3. The first main surface 21 is rectangular in shape. As used herein, a rectangular shape includes a corner chamfered rectangular shape. The rectangle may be a square. The second main surface 22 faces in the direction opposite to the direction in which the first main surface 21 faces. The second main surface 22 is also rectangularly shaped, similar to the first main surface 21.

The glass substrate 2 also includes four end faces 23, four first chamfering surfaces 24, and four second chamfering surfaces 25. The end faces 23 are perpendicular to the first main surface 21 and the second main surface 22. The first chamfering surfaces 24 are formed at a boundary between the first main surface 21 and the end surface 23. The second chamfering surfaces 25 are formed at a boundary between the second main surface 22 and the end surface 23. The first chamfering surfaces 24 and the second chamfering surfaces 25 are chamfering surfaces in the present embodiment, but may be rounded surfaces.

Glass of the glass substrate 2 is preferably quartz glass containing TiO₂. Quartz glass has a smaller coefficient of linear expansion and a smaller dimensional change caused by a temperature change than typical soda lime glass. Quartz glass may contain from 80% through 95% by mass of SiO₂ and from 4% through 17% by mass of TiO₂. If the TiO₂ content is from 4% through 17% by weight, the linear expansion coefficient near room temperature is almost zero, and there is little dimensional change around room temperature. Quartz glass may contain a third component or impurity other than SiO₂ and TiO₂.

A size of the glass substrate 2 is, for example, 152 mm in a vertical direction and 152 mm in a horizontal direction in plan view. The vertical and horizontal dimensions may be 152 mm or more.

The glass substrate 2 has a central area 27 and a peripheral area 28 on the first main surface 21. The central area 27 is a square area of 142 mm in a vertical direction and 142 mm in a horizontal direction, excluding the rectangular frame-like peripheral area 28 surrounding the central area 27, which is machined to have desired flatness by steps S1-S4 of FIG. 1. Four sides of the central area 27 are parallel to the four end faces 23. A center of the central area 27 coincides with a center of the first main surface 21.

Although not depicted, the second main surface 22 of the glass substrate 2 also has a central area and a peripheral area, similar to the first main surface 21. The central area of the second main surface 22 is a square area of 142 mm in a vertical direction and 142 mm in a horizontal direction, similar to the central area of the first main surface 21, which is machined to have a desired flatness by steps S1-S4 of FIG. 1.

First, in step S1, the first main surface 21 and the second main surface 22 of the glass substrate 2 are polished. According to the present embodiment, the first main surface 21 and the second main surface 22 are polished simultaneously by a double-side polishing machine 9 that will be described later, but may be polished sequentially by a single-side polishing machine (not depicted). In step S1, the glass substrate 2 is polished while polishing slurry is supplied to between a polishing pad and the glass substrate 2.

Examples of the polishing pad include a urethane polishing pad, a nonwoven polishing pad, and a suede polishing pad. The polishing slurry includes an abrasive and a dispersion medium. The abrasive is, for example, cerium oxide particles. The dispersion medium may be, for example, water or an organic solvent. The first main surface 21 and the second main surface 22 may be polished multiple times with abrasives of different materials or of different particle sizes.

The abrasive used in step S1 is not limited to cerium oxide particles. For example, the abrasive used in step S1 may be silicon oxide particles, aluminum oxide particles, zirconium oxide particles, titanium oxide particles, diamond particles, silicon carbide particles, or the like.

Next, in step S2, surface geometries of the first main surface 21 and the second main surface 22 of the glass substrate 2 are measured. For example, a non-contact measuring apparatus, such as a measuring apparatus of a laser interference type, is used to measure surface geometries, so as to prevent the surfaces from being damaged. The measuring apparatus is used to measure surface geometries of the central area 27 of the first main surface 21 and the central area of the second main surface 22.

Next, in step S3, referring to the measurement result of step S2, the first main surface 21 and the second main surface 22 of the glass substrate 2 are locally machined in order to improve flatness. The first main surface 21 and the second main surface 22 are locally machined in sequence. Either one can be locally machined first, and thus is not particularly limited. A method of locally machining may be, for example, a GCIB method or a PCVM method. A method of locally machining may be a magnetic fluid polishing method or a polishing method using a rotary polishing tool.

Next, in step S4, final polishing of the first main surface 21 and the second main surface 22 of the glass substrate 2 is performed. In the present embodiment, the first main surface 21 and the second main surface 22 are polished simultaneously by a double-side polishing machine 9 that will be described later, but may be polished sequentially by a single-side polishing machine (not depicted). In step S4, the glass substrate 2 is polished while polishing slurry is supplied to between a polishing pad and the glass substrate 2. The polishing slurry includes an abrasive. The abrasive is, for example, colloidal silica particles.

Next, in step S5, a conductive film 5 depicted in FIG. 4 is formed on the central area 27 of the first main surface 21 of the glass substrate 2. The conductive film 5 is used to cause a photomask for EUVL to be attracted by an electrostatic chuck of an exposure apparatus. The conductive film 5 is formed of, for example, chromium nitride (CrN). For example, a sputtering method is used as a method of forming the conductive film 5.

Next, in step S6, an EUV reflective film 3 depicted in FIG. 4 is formed on the central area of the second main surface 22 of the glass substrate 2. The EUV reflective film 3 reflects EUV light. The EUV reflective film 3 may be, for example, a multi-layer reflective film in which high refractive index layers and low refractive index layers are alternately laminated. The high refractive index layers are formed, for example, of silicon (Si), and the low refractive index layers are formed, for example, of molybdenum (Mo). As a method of forming the EUV reflective film 3, for example, a sputtering method such as an ion beam sputtering method or a magnetron sputtering method is used.

Finally, in step S7, an EUV absorbing film 4 depicted in FIG. 4 is formed on the EUV reflective film 3 formed in step S6. The EUV absorbing film 4 absorbs EUV light. The EUV absorbing film 4 is formed of, for example, a single metal, an alloy, a nitride, an oxide, an oxynitride, or the like, or any combination thereof. The single metal contains at least one element selected from tantalum (Ta), chromium (Cr), and palladium (Pd). For example, a sputtering method is used as a method of forming the EUV absorbing film 4.

Steps S6-S7 are performed after step S5 in the present embodiment, but may be performed before step S5.

Steps S1-S7 thus provide a mask blank 1 depicted in FIG. 4. The mask blank 1 has the first main surface 11 and the second main surface 12 facing in a direction opposite to a direction in which the first main surface 11 faces, and has the conductive film 5, the glass substrate 2, the EUV reflective film 3, and the EUV absorbing film 4 in the stated order from the first main surface 11 side to the second main surface 12 side.

The mask blank 1 has, although not depicted, a central area and a peripheral area on the first main surface 11, similar to the glass substrate 2. The central area is a square area of 142 mm in a vertical direction and 142 mm in a horizontal direction, excluding the rectangular frame-like peripheral area surrounding the central area. Similarly to the glass substrate 2, the mask blank 1 has a central area and a peripheral area also on the second main surface 12. The central area is a square area of 142 mm in a vertical direction and 142 mm in a horizontal direction, excluding the rectangular frame-like peripheral area surrounding the central area.

The mask blank 1 may include another film in addition to the conductive film 5, the glass substrate 2, the EUV reflective film 3, and the EUV absorbing film 4.

For example, the mask blank 1 may further include a low-reflective film. The low-reflective film is formed on the EUV absorbing film 4. A circuit pattern 41 is then formed on both the low-reflective film and the EUV absorbing film 4. The low-reflective film is used for inspection of the circuit pattern 41 and has a lower reflectivity with respect to inspection light than the EUV absorbing film 4. The low-reflective film may be formed, for example, of TaON or TaO. For example, a sputtering method is used as a method of forming a low-reflective film.

The mask blank 1 may also include a protective film. The protective film is formed between the EUV reflective film 3 and the EUV absorbing film 4. The protective film protects the EUV reflective film 3 so as to prevent the EUV reflective film 3 from being etched during etching of the EUV absorbing film 4 to form a circuit pattern 41 onto the EUV absorbing film 4. The protective film may be formed of, for example, Ru, Si, or TiO₂. As a method of forming the protective film, for example, a sputtering method is used.

As depicted in FIG. 5, the EUVL photomask is obtained by forming a circuit pattern 41 onto the EUV absorbing film 4. The circuit pattern 41 is an opening pattern, photolithography and etching methods being used to form the circuit pattern 41. Therefore, a resist film used to form the circuit pattern 41 may be included in the mask blank 1.

The mask blank 1 is to have high flatness in order to improve the circuit pattern 41 transferring accuracy. The flatness mainly depends on flatness of the glass substrate 2. Therefore, the glass substrate 2 is to have high flatness also.

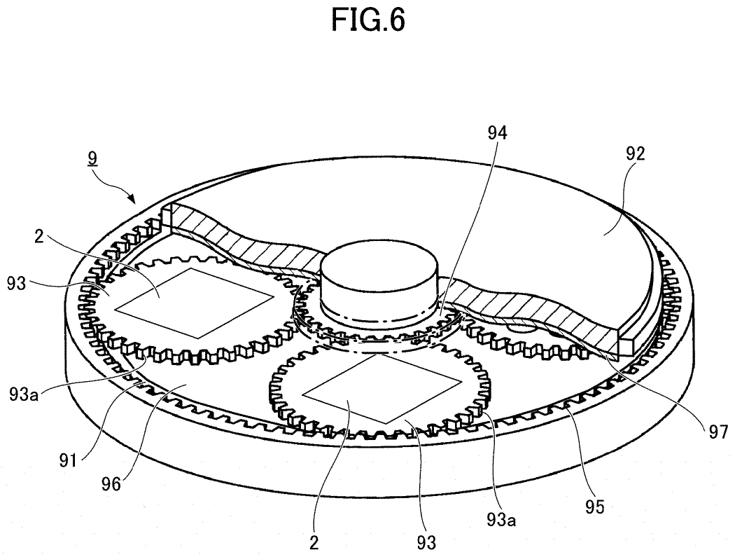

Therefore, as described above, the glass substrate 2 is subjected to polishing (step S1), local machining (step S3), and final polishing (step S4) in the stated order. In the final polishing, the glass substrate 2 is pressed against a platen while the glass substrate 2 and the platen are being rotated. For the final polishing, for example, the double-side polishing machine 9 depicted in FIG. 6 is used.

The double-side polishing machine 9 includes a lower platen 91, an upper platen 92, carriers 93, a sun gear 94, and an internal gear 95. The lower platen 91 is positioned horizontally and a lower polishing pad 96 is affixed to an upper surface of the lower platen 91. The upper platen 92 is positioned horizontally and the upper polishing pad 97 is affixed to a lower surface of the upper platen 92. The carriers 93 hold glass substrates 2 horizontally between the lower platen 91 and the upper platen 92. Each carrier 93 holds one glass substrate 2, but may also hold a plurality of glass substrates 2. The carriers 93 are disposed radially outside of the sun gear 94 and radially inside of the internal gear 95. The plurality of carriers 93 are spaced apart from each other around the sun gear 94. The sun gear 94 and the internal gear 95 are arranged concentrically and engage with the outer peripheral gears 93a of the carriers 93.

The double-side polishing machine 9 is, for example, of a so-called four-way type, and the lower platen 91, the upper platen 92, the sun gear 94, and the internal gear 95 rotate about a common vertical rotational centerline. The lower platen 91 and the upper platen 92 rotate in reverse directions while pressing the lower polishing pad 96 against a lower surface of the glass substrate 2 and pressing the upper polishing pad 97 against an upper surface of the glass substrate 2. At least one of the lower platen 91 and the upper platen 92 supplies polishing slurry to the glass substrate 2. The polishing slurry is supplied to between the glass substrate 2 and the lower polishing pad 96 to polish the lower surface of the glass substrate 2. The polishing slurry is supplied to between the glass substrate 2 and the upper polishing pad 97 to polish the upper surface of the glass substrate 2.

For example, the lower platen 91, the sun gear 94, and the internal gear 95 rotate in the same direction in a plan view. This rotation direction is reverse to the rotation direction of the upper platen 92. The carriers 93 rotate while revolving. The revolving directions of the carriers 93 are the same as the rotation directions of the sun gear 94 and the internal gear 95. On the other hand, the rotation directions of the carriers 93 are determined by whether a product of a rotational speed and a pitch circle diameter of the sun gear 94 or a product of a rotational speed and a pitch circle diameter of the internal gear 95 is greater than the other. If the product of the rotational speed and the pitch circle diameter of the internal gear 95 is greater than the product of the rotational speed and the pitch circle diameter of the sun gear 94, the rotation directions of the carriers 93 are the same as the revolving directions of the carriers 93. On the other hand, if the product of the rotational speed and the pitch circle diameter of the internal gear 95 is smaller than the product of the rotational speed and the pitch circle diameter of the sun gear 94, the rotation directions of the carriers 93 are reverse to the revolving directions of the carriers 93.

The first main surface 21 and the second main surface 22 of the glass substrate 2 are polished by the double-side polishing machine 9 axisymmetrically around their respective centers. The first main surface 21 and the second main surface 22 tend to be polished plane-symmetrically with respect to a central plane with respect to a plate thickness direction of the glass substrate 2. Both of the first main surface 21 and the second main surface 22 tend to be polished to convex surfaces or both of the first main surface 21 and the second main surface 22 tend to be polished to concave surfaces. In final polishing, a single-side polishing machine (not depicted) may be used as described above.

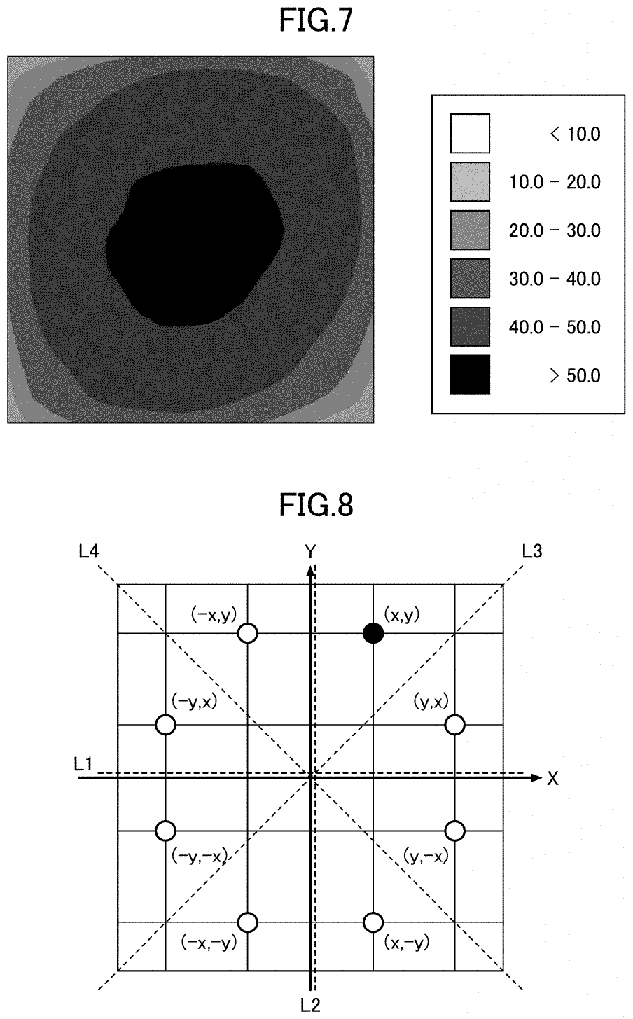

FIG. 7 depicts an example of a height distribution with respect to the central area 27 of the first main surface 21 after final polishing. FIG. 7 depicts the height distribution after tilt correction. The central area 27 depicted in FIG. 7 is a convex surface having a center height greater than four corner heights. The unit of height in FIG. 7 is nm, and the greater the value, the higher the height. Because a height distribution with respect to the central area of the second main surface 22 after final polishing is the same as the height distribution depicted in FIG. 7, indication of the height distribution with respect to the central area of the second main surface 22 after final polishing is omitted.

The height distribution depicted in FIG. 7 was measured by UltraFlat200Mask manufactured by the Corning Tropel company. In order to eliminate influence of the gravity, the glass substrate 2 is placed generally vertically, and the height distribution is measured in a state where the glass substrate 2 is supported in such a manner that both the first main surface 21 and the second main surface 22 of the glass substrate 2 do not contact other members such as a stage.

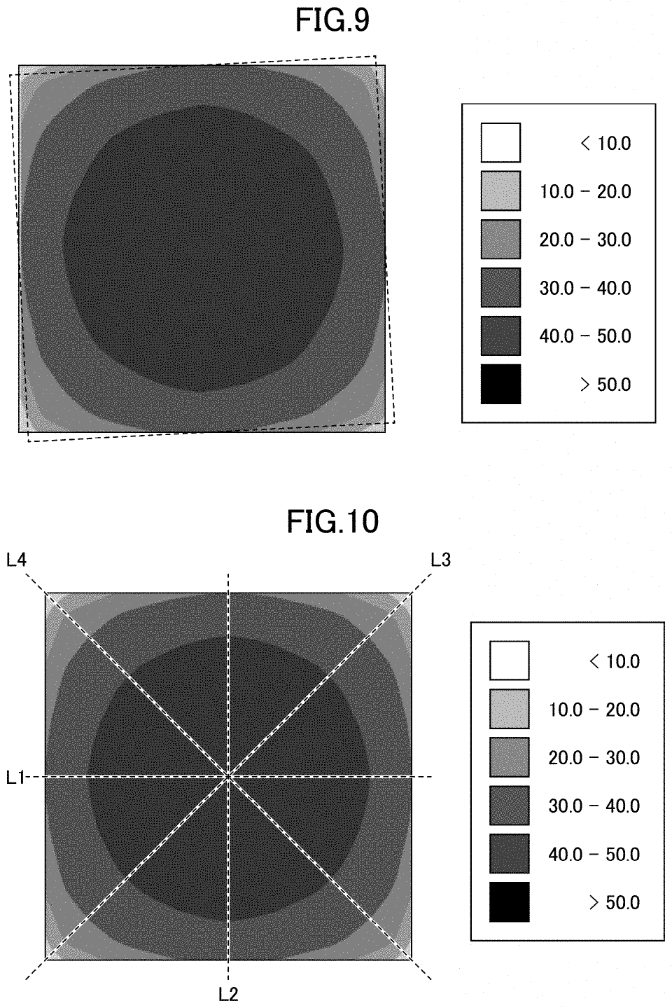

As can be seen from FIG. 7, the central area 27 of the first main surface 21 after final polishing is not perfectly axisymmetric, and includes perfect axisymmetric components with the rest being distortion components. The distortion components, which will be described in detail later, include fourfold rotationally symmetric components with respect to rotation about a center of the central area 27, as depicted in FIG. 9. The fourfold rotationally symmetric components are produced through the final polishing.

The fourfold rotationally symmetric components are preferably expressed by a Zernike polynomial rather than a Legendre polynomial. A Zernike polynomial, unlike a Legendre polynomial, is expressed by polar coordinates and is suitable for removing axisymmetric components.

However, unlike a Legendre polynomial, a Zernike polynomial can express only a circular area. The central area 27 is rectangular, and four corners of the rectangle cannot be expressed by a Zernike polynomial. Therefore, in the related art, distortion components generated through final polishing cannot be accurately identified.

Thus, in the present embodiment, coordinates of points on the central area 27 of a square of 142 mm in a vertical direction and 142 mm in a horizontal direction are expressed by (x, y, z(x,y)), and distortion components are identified by using the following Formulas (1) through (3).

$$\{ \begin{matrix}z 1 ( x , y ) = \{ z ( x , y ) + z ( y , - x ) + z ( - x , - y ) + z ( - y , x ) \} / 4 \\ z 2 ( x , y ) = \{ \begin{matrix}z ( x , y ) + z ( y , x ) + z ( y , - x ) + z ( x , - y ) + \\ z ( - x , - y ) + z ( - y , - x ) + z ( - y , x ) + z ( - x , y )\end{matrix} \} / 8 \\ z 3 ( x , y ) = z 1 ( x , y ) - z 2 ( x , y )\end{matrix} \qquad \begin{matrix}\begin{matrix}( 1 ) \\ ( 2 )\end{matrix} \\ \\ ( 3 )\end{matrix}$$

In the above-mentioned coordinates (x, y, z(x,y)), x denotes a vertical-direction coordinate, y denotes a horizontal-direction coordinate, z denotes a height-direction coordinate; and the vertical, horizontal, and height directions are perpendicular to one another. FIG. 8 depicts an example of an arrangement of multiple points set on the central area 27. In FIG. 8, an x-axis direction is a horizontal direction and a y-axis direction is a vertical direction. An origin, which is an intersection of the x-axis and the y-axis, is a center of the central area 27.

As can be seen from FIG. 8, z1(x,y) in Formula (1) is an average of heights of four points that are fourfold rotationally symmetric with respect to rotation about the origin. A height distribution with respect to a surface that is a set of coordinates (x, y, z1(x,y)) is depicted in FIG. 9. The unit of height in FIG. 9 is nm, and the greater the value, the higher the height. The height distribution depicted in FIG. 9 includes fourfold rotationally symmetric components with respect to rotation about the origin, in addition to axisymmetric components. The fourfold rotationally symmetric components are those rotated counterclockwise, for example, as depicted by a dashed line in FIG. 9.

As can be seen from FIG. 8, z2(x,y) in Formula (2) is an average of heights of eight points that are line symmetrical with respect to four baselines L1-L4 passing through the origin. The baseline L1 is the x-axis, the baseline L2 is the y-axis, and the baselines L3 and L4 are diagonal lines of the central area 27. A height distribution with respect to a surface that is a set of coordinates (x, y, z2(x,y)) is depicted in FIG. 10. The unit of height in FIG. 10 is nm, and the greater the value, the higher the height. The height distribution depicted in FIG. 10 includes only components that are approximately axisymmetric.

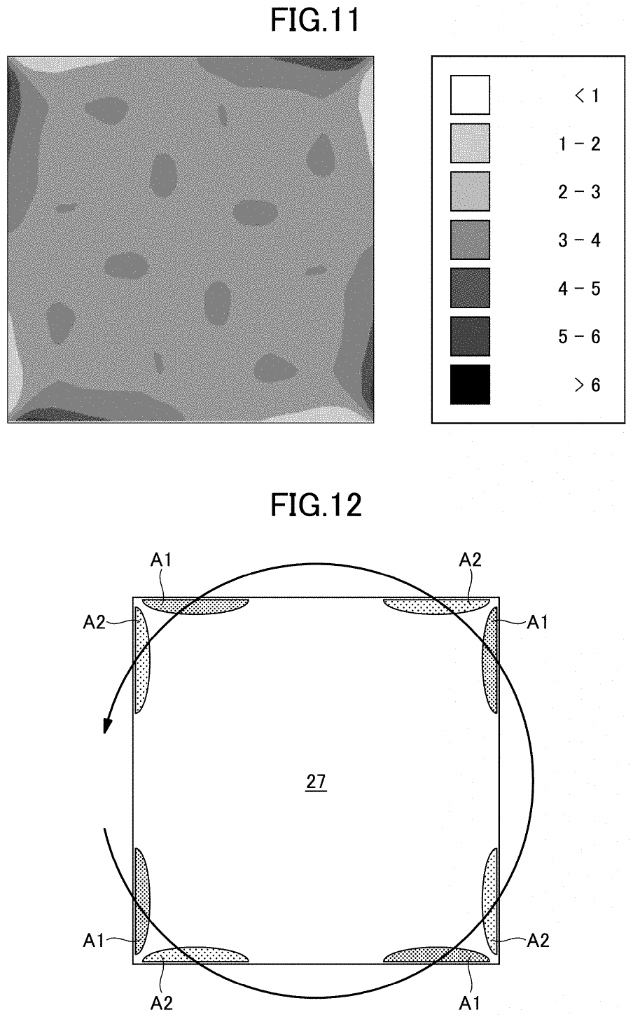

z3(x,y) in Formula (3) is a difference between z1(x,y) in Formula (1) and z2(x,y) in Formula (2). A height distribution with respect to a surface that is a set of coordinates (x, y, z3(x,y)) is depicted in FIG. 11. The unit of height in FIG. 11 is nm, and the greater the value, the higher the height. The height distribution depicted in FIG. 11 is the difference between the height distribution depicted in FIG. 9 and the height distribution depicted in FIG. 10, and includes fourfold rotationally symmetric components with respect to rotation with respect to the origin as major components.

Next, a reason why the height distribution depicted in FIG. 11 is generated through final polishing will be described with reference to FIG. 12. An arrow depicted in FIG. 12 depicts a relative rotational direction of a platen (e.g., the lower platen 91 or the upper platen 92) relative to the central area 27. That is, the arrow depicted in FIG. 12 indicates a direction of rotation of the platen with respect to a coordinate system fixed to the central area 27.

In four corners of the central area 27, polishing of each of portions A1 at an upstream side with respect to the rotation direction of the platen is easily advanced, whereas polishing of each of portions A2 at a downstream side with respect to the rotation direction of the platen is not easily advanced. From this viewpoint, it can be considered that the height distribution depicted in FIG. 11 is generated through final polishing.

The inventor of the present invention found through an experiment, etc., that flatness PV (PV≥0) of the central area 27 can be controlled such that the flatness PV is less than 10.0 nm, as a result of the maximum height difference Δz3 (Δz3≥0) of the surface that is the set of coordinates (x, y, z3(x,y)) being 6.0 nm or less.

In the present disclosure, the flatness PV of the central area 27 corresponds to the maximum height difference of components that remain after excluding, from all components of the height distribution with respect to the central area 27, components indicated by a quadratic function. The quadratic function is expressed by Formula (4) below.

z_{fit}(x,y)=a+bx+cy+dxy+ex²+fy² (4)

In Formula (4) above, a, b, c, d, e, and f are constants determined in such a manner that a sum of squares of differences between z_{fit}(x,y) and z(x,y) is minimized, and are constants determined by a least-squares method.

The components with respect to the quadratic function are components that can be automatically corrected by an exposure apparatus. Accordingly, the components with respect to the quadratic function do not affect transfer accuracy with respect to a circuit pattern 41. Therefore, the components with respect to the quadratic function are thus excluded from all components of the height distribution with respect to the central area 27 when determining the flatness PV of the central area 27.

In order to control Δz3 such that Δz3 is 6.0 nm or less, the inventor of the present invention first performed steps S1-S4 described above on another glass substrate 2 in advance, and calculated a difference in height z_{dif}(x,y) at each point of the central area 27 before and after final polishing using the following Formula (5). Then, z_{4_dif}(x,y) was calculated using Formula (6) below.

$$\{ \begin{matrix}{z}_{dif} ( x , y ) = {z}_{after} ( x , y ) - {z}_{before} ( x , y ) \\ {z}_{4 \_dif} ( x , y ) = \{ {z}_{dif} ( x , y ) + {z}_{dif} ( y , - x ) + {z}_{dif} ( - x , - y ) + {z}_{dif} ( - y , x ) \} / 4\end{matrix} \qquad \begin{matrix}( 5 ) \\ ( 6 )\end{matrix}$$

In Formula (5), z_{after}(x,y) is a height at coordinates (x,y) after final polishing, and z_{before}(x,y) is a height at the coordinates (x,y) after local machining and before final polishing. Because a difference between z_{after}(x,y) and z_{before}(x,y) is z_{dif}(x,y), z_{dif}(x,y) depicts a distribution of amounts of polishing in final polishing.

z_{4_dif}(x,y) in Formula (6) above is an average of four points that are fourfold rotationally symmetric with respect to rotation about the origin. Accordingly, z_{4_dif}(x,y) of the above-described Formula (6) relates to components that are fourfold rotationally symmetric among the above-described distortion components, and corresponds to z3(x,y) of the above-described Formula (3).

The inventor of the present invention found that Δz3 can be controlled such that Δz3 is 6.0 nm or less by correcting a target height of each point of the central area 27 with respect to local machining (step S3) using a previously calculated z_{4_dif}(x,y). As a result, the glass substrate 2 having PV of less than 10.0 nm was able to be obtained.

The corrected target height is obtained from a difference between a target height set based on a measurement result of step S2 and a previously calculated z_{4_dif}(x,y). In other words, a target machining amount after the correction is obtained from a sum of a target machining amount determined based on a measurement result of step S2 and a previously calculated z_{4_dif}(x,y). z_{4_dif}(x,y) used for the correction is preferably an average value with respect to a plurality of glass substrates 2. The average value of z_{4_dif}(x,y) is determined for each finish polishing condition (e.g., a type of abrasive; a type, a polish pressure, and a rotational speed of a polishing pad; etc.).

In addition, noticing that distortion components generated through final polishing (step S4) are generated from a relative rotation of the platen with respect to the glass substrate 2, the inventor of the present invention found that, by reversing a rotation direction of the platen during final polishing, it was possible to control Δz3 such that Δz3 was 4.0 nm or less. As a result, the glass substrate 2 having PV of less than 8.0 nm was able to be obtained.

Specifically, in the middle of final polishing (step S4), rotation directions of the lower platen 91 and the upper platen 92 are reversed, respectively. At this time, rotation directions of the sun gear 94 and the internal gear 95 are also reversed, respectively. In this case, as long as the directions of rotations are reversed, the rotational speeds may be kept unchanged. As described above, a single-side polishing machine may be used for the final polishing.

As a result of the rotation directions of the platens being thus reversed during final polishing, the direction of the arrow depicted in FIG. 12 is reversed, and the portions where polishing are advanced and the portions where polishing is not advanced are replaced with each other. In final polishing, a time during which the platens rotate in respective directions is set to be the same as or to be similar to a time during which the platens rotate reverse directions, respectively. As a result, Δz3 can be controlled such that Δz3 is 4.0 nm or less.

In a case where the rotation directions of the platens are reversed during final polishing, z_{8_dif}(x,y) of the following Formula (7) is used instead of z_{4_dif}(x,y) of the above-described Formula (6), when correcting target heights or target processing amounts in local machining.

z_{8_dif}(x,y)={z_{dif}(x,y)+z_{dif}(y,x)+z_{dif}(y,−x)+z_{dif}(x,−y)+z_{dif}(−x,−y)+z_{dif}(−y,−x)+z_{dif}(−y,x)+z_{dif}(−x,y)}/8 (7)

z_{8_dif}(x,y) in Formula (7) above is an average of eight points that are line symmetrical with respect to four baselines L1-L4. By thus using the eight-point average z_{8_dif}(x,y) instead of the four-point average z_{4_dif}(x,y), it is possible to increase the number of samples and reduce errors.

Although z_{8_dif}(x,y), which is an average of 8 points, does not include fourfold rotationally symmetric components depicted in FIG. 11, there is no problem. This is because fourfold rotationally symmetric components depicted in FIG. 11 are reduced as a result of rotational directions of the platens being reversed during final polishing.

In a case where rotation directions of the platens are thus reversed during final polishing, a corrected target height is obtained from a difference between a target height determined based on a measurement result of step S2 and a previously calculated z_{8_dif}(x,y). In other words, a target machining amount after correction is obtained from a sum of a target machining amount determined based on a measurement result of step S2 and a previously calculated z_{8_dif}(x,y). z_{8_dif}(x,y) used for the correction is preferably an average value of a plurality of glass substrates 2. The average value of z_{8_dif}(x,y) is determined for each finish polishing condition (e.g., a type of abrasive; a type, a polish pressure, and a rotational speed of a polishing pad; etc.).

The description has been thus made for the central area 27 of the first main surface 21 of the glass substrate 2. However, the same applies to the central area of the second main surface 22 of the glass substrate 2. As a result of Δz3 being controlled such that Δz3 is 6.0 nm or less, also PV of the central area of the second main surface 22 can be controlled such that PV is less than 10.0 nm.

Flatness of the first main surface 11 of the mask blank 1 depends on flatness of the first main surface 21 of the glass substrate 2. Therefore, as a result of Δz3 being controlled such that Δz3 is 6.0 nm or less, also PV of the central area of the first main surface 11 can be controlled such that PV is 15.0 nm or less, preferably, is less than 10.0 nm.

Furthermore, flatness of the second main surface 12 of the mask blank 1 depends on flatness of the second main surface 22 of the glass substrate 2. Accordingly, also PV of the central area of the second main surface 12 can be controlled such that PV is 15.0 nm or less, preferably, is less than 10.0 nm, by controlling Δz3 such that Δz3 is 6.0 nm or less.

### EXAMPLES

In each of Examples 1-7, steps S1-S4 described with reference to FIG. 1 were performed under the same conditions except for the following conditions, to prepare a glass substrate 2, and measure Δz3 and PV for the central area 27 of the first main surface 21. In each of Examples 1-3, rotation directions of the platens were reversed during final polishing, and target heights with respect to local machining were corrected using previously calculated average values of z_{8_dif}(x,y). In each of Examples 4-5, rotational directions of the platens were kept unchanged during final polishing, and target heights with respect to local machining were corrected using previously calculated average values of z_{4_dif}(x,y). In contrast, in each Examples 6-7, rotational directions of the platens were kept unchanged during final polishing, and target heights with respect to local machining were determined using measurement results of step S2 without using previously calculated average values of z_{4_dif}(x,y). Examples 1-5 are examples of the present embodiment, and Examples 6-7 are comparative examples. The results are depicted in Table 1 below.

TABLE 1

| | EXAMPLE 1 | EXAMPLE 2 | EXAMPLE 3 | EXAMPLE 4 | EXAMPLE 5 | EXAMPLE 6 | EXAMPLE 7 |
|---|---|---|---|---|---|---|---|
| Δ z3 | 2.1 | 2.8 | 3.8 | 4.2 | 5.2 | 7.7 | 8.2 |
| (nm) | | | | | | | |
| PV | 7.4 | 7.7 | 7.7 | 8.0 | 8.5 | 12.8 | 13.9 |
| (nm) | | | | | | | |

As can be seen from Table 1, in each of Examples 1-3, rotation directions of the platens were reversed during final polishing, and target heights with respect to local machining were corrected using previously calculated averages value of z_{8_dif}(x,y). Then, Δz3 was controlled such that Δz3 was 4.0 nm or less, and PV was controlled such that PV was less than 8.0 nm. In each of Examples 4-5, rotation directions of the platens were kept unchanged during final polishing and target heights with respect to local machining were corrected using previously calculated average values of z_{4_dif}(x,y). Then, Δz3 was controlled such that Δz3 was 6.0 nm or less, and PV was controlled such that PV was less than 10.0 nm. In contrast, in each of Examples 6-7, rotational directions of the platens were kept unchanged during final polishing and target heights with respect to local machining were set using measurement results of step S2 without using previously calculated average values of z_{4_dif}(x,y). Then, Δz3 was more than 6.0 nm, and PV was 10.0 nm or more.

Next, mask blanks 1 for EUVL were prepared using the glass substrates 2 of Examples 1-7, respectively. In each of the Examples 1-7, first, a CrN film was formed with a thickness of 100 nm as a conductive film on the first main surface 21 of the glass substrate 2 (for which Δz3 and PV were measured) by an ion beam sputtering method. Then, a multi-layer reflective film (an EUV reflective film) was formed on the second main surface 22 of the glass substrate 2 by an ion beam sputtering method. The multi-layer reflective film was made by alternately laminating an about 4 nm Si film and an about 3 nm Mo film for 40 cycles and finally laminating an about 4 nm Si film. Subsequently, a Ru film was formed as a protective film with a thickness of 2.5 nm by a sputtering method on the multi-layer reflective film. Subsequently, a TaN film was formed with a thickness of 75 nm and a TaON film was formed with a thickness of 5 nm by a sputtering method on the protective film, as an absorbing film (an EUV absorbing film). In this way, the mask blanks 1 for EUVL, each including the conductive film 5, the glass substrate 2, the EUV reflective film 3, and the EUV absorbing film 4 in the stated order, were obtained.

Δz3 and PV were measured for the central areas of the first main surfaces 11 (the surfaces on the conductive film 5 sides) of the mask blanks 1 for EUVL manufactured using the glass substrates 2 of Examples 1-7, respectively. Table 2 below depicts the results.

TABLE 2

| | | EXAMPLE 1 | EXAMPLE 2 | EXAMPLE 3 | EXAMPLE 4 | EXAMPLE 5 | EXAMPLE 6 | EXAMPLE 7 |
|---|---|---|---|---|---|---|---|---|
| GLASS | Δ z3 | 2.1 | 2.8 | 3.8 | 4.2 | 5.2 | 7.7 | 8.2 |
| SUBSTRATE | (nm) | | | | | | | |
| FIRST MAIN | PV | 7.4 | 7.7 | 7.7 | 8.0 | 8.5 | 12.8 | 13.9 |
| SURFACE | (nm) | | | | | | | |
| MASK BLANK | Δ z3 | 2.8 | 3.3 | 4.1 | 4.4 | 5.6 | 9.5 | 10.6 |
| FIRST MAIN | (nm) | | | | | | | |
| SURFACE | PV | 14.1 | 14.2 | 14.3 | 14.4 | 14.6 | 16.6 | 17.2 |
| | (nm) | | | | | | | |

As depicted in Table 2, in each of Examples 1-5, Δz3 was able to be controlled such that Δz3 was 6.0 nm or less and PV was able to be controlled such that PV was 15.0 nm or less in the central area of the first main surface 11 of the mask blank 1 for EUVL. In contrast, in each of Examples 6 and 7, for the central area of the first main surface 11 of the mask blank 1 for EUVL, Δz3 was more than 6.0 nm, and PV was more than 15.0 nm.

Thus, although the glass substrates for EUVL and the mask blanks for EUVL have been described with reference to the embodiments, the present invention is not limited to the embodiments and so forth. Various variations, modifications, substitutions, additions, deletions, and combinations can be made without departing from the claimed scope that will now be described. The various variations, modifications, substitutions, additions, deletions, and combinations are covered by the present invention.

What is claimed is:

1. A glass substrate for extreme ultra-violet lithography (EUVL) comprising a first main surface rectangular in shape, a conductive film being formed on the first main surface; and a second main surface rectangular in shape and facing in a direction opposite to a direction in which the first main surface faces, an EUV reflective film and an EUV absorbing film being formed in a stated order on the second main surface,
wherein
when coordinates of points included in a central area of the first main surface excluding a rectangular frame-like peripheral area are expressed by (x, y, z(x,y)), the central area having a square shape of 142 mm in a vertical direction and 142 mm in a horizontal direction, a maximum height difference of a surface that is a set of coordinates (x, y, z3(x,y)) calculated by using Formulas (1)-(3) below is 6.0 nm or less,
$$\{ \begin{matrix}z 1 ( x , y ) = \{ z ( x , y ) + z ( y , - x ) + z ( - x , - y ) + z ( - y , x ) \} / 4 \\ z 2 ( x , y ) = \{ \begin{matrix}z ( x , y ) + z ( y , x ) + z ( y , - x ) + z ( x , - y ) + \\ z ( - x , - y ) + z ( - y , - x ) + z ( - y , x ) + z ( - x , y )\end{matrix} \} / 8 \\ z 3 ( x , y ) = z 1 ( x , y ) - z 2 ( x , y )\end{matrix} \qquad \begin{matrix}\begin{matrix}( 1 ) \\ ( 2 )\end{matrix} \\ \\ ( 3 )\end{matrix}$$
wherein
in the coordinates (x, y, z(x,y)), x denotes a coordinate with respect to the horizontal direction, y denotes a coordinate with respect to the vertical direction, z denotes a coordinate with respect to a height direction, and the horizontal, vertical, and height directions are perpendicular to one another.

2. A glass substrate for extreme ultra-violet lithography (EUVL) comprising a first main surface rectangular in shape, a conductive film being formed on the first main surface; and a second main surface rectangular in shape and facing in a direction opposite to a direction in which the first main surface faces, an EUV reflective film and an EUV absorbing film being formed in a stated order on the second main surface,
wherein
when coordinates of points included in a central area of the second main surface excluding a rectangular frame-like peripheral area, the central area having a square shape of 142 mm in a vertical direction and 142 mm in a horizontal direction, are expressed by (x, y, z(x,y)), a maximum height difference of a surface that is a set of coordinates (x, y, z3(x,y)) calculated using Formulas (1)-(3) below is 6.0 nm or less,
$$\{ \begin{matrix}z 1 ( x , y ) = \{ z ( x , y ) + z ( y , - x ) + z ( - x , - y ) + z ( - y , x ) \} / 4 \\ z 2 ( x , y ) = \{ \begin{matrix}z ( x , y ) + z ( y , x ) + z ( y , - x ) + z ( x , - y ) + \\ z ( - x , - y ) + z ( - y , - x ) + z ( - y , x ) + z ( - x , y )\end{matrix} \} / 8 \\ z 3 ( x , y ) = z 1 ( x , y ) - z 2 ( x , y )\end{matrix} \qquad \begin{matrix}\begin{matrix}( 1 ) \\ ( 2 )\end{matrix} \\ \\ ( 3 )\end{matrix}$$
wherein
in the coordinates (x, y, z(x,y)), x denotes a coordinate with respect to the horizontal direction, y denotes a coordinate with respect to the vertical direction, z denotes a coordinate with respect to a height direction, and the horizontal, vertical, and height directions are perpendicular to one another.

3. A mask blank for extreme ultra-violet lithography (EUVL) comprising a first main surface rectangular in shape and a second main surface rectangular in shape and facing in a direction opposite to a direction in which the first main surface faces, wherein the mask blank further comprises a conductive film, a glass substrate, an EUV reflective film, and an EUV absorbing film in a stated order from the first main surface side to the second main surface side,
wherein
when coordinates of points included in a central area of the first main surface excluding a rectangular frame-like peripheral area are expressed by (x, y, z(x,y)), the central area having of a square shape of 142 mm in a vertical direction and 142 mm in a horizontal direction, a maximum height difference of a surface that is a set of coordinates (x, y, z3(x,y)) calculated by using Formulas (1)-(3) below is 6.0 nm or less,
$$\{ \begin{matrix}z 1 ( x , y ) = \{ z ( x , y ) + z ( y , - x ) + z ( - x , - y ) + z ( - y , x ) \} / 4 \\ z 2 ( x , y ) = \{ \begin{matrix}z ( x , y ) + z ( y , x ) + z ( y , - x ) + z ( x , - y ) + \\ z ( - x , - y ) + z ( - y , - x ) + z ( - y , x ) + z ( - x , y )\end{matrix} \} / 8 \\ z 3 ( x , y ) = z 1 ( x , y ) - z 2 ( x , y )\end{matrix} \qquad \begin{matrix}\begin{matrix}( 1 ) \\ ( 2 )\end{matrix} \\ \\ ( 3 )\end{matrix}$$
wherein
in the coordinates (x, y, z(x,y)), x denotes a coordinate with respect to the horizontal direction, y denotes a coordinate with respect to the vertical direction, z denotes a coordinate with respect to a height direction, and the horizontal, vertical, and height directions are perpendicular to one another.

4. A mask blank for extreme ultra-violet lithography (EUVL) comprising a first main surface rectangular in shape and a second main surface rectangular in shape and facing in a direction opposite to a direction in which the first main surface faces, wherein the mask blank further comprises a conductive film, a glass substrate, an EUV reflective film, and an EUV absorbing film in a stated order from the first main surface side to the second main surface side,
wherein
when coordinates of points included in a central area of the second main surface excluding a rectangular frame-like peripheral area are expressed by (x, y, z(x,y)), the central area having a square shape of 142 mm in a vertical direction and 142 mm in a horizontal direction, a maximum height difference of a surface that is a set of coordinates (x, y, z3(x,y)) calculated by using Formulas (1)-(3) below is 6.0 nm or less,
$$\{ \begin{matrix}z 1 ( x , y ) = \{ z ( x , y ) + z ( y , - x ) + z ( - x , - y ) + z ( - y , x ) \} / 4 \\ z 2 ( x , y ) = \{ \begin{matrix}z ( x , y ) + z ( y , x ) + z ( y , - x ) + z ( x , - y ) + \\ z ( - x , - y ) + z ( - y , - x ) + z ( - y , x ) + z ( - x , y )\end{matrix} \} / 8 \\ z 3 ( x , y ) = z 1 ( x , y ) - z 2 ( x , y )\end{matrix} \qquad \begin{matrix}\begin{matrix}( 1 ) \\ ( 2 )\end{matrix} \\ \\ ( 3 )\end{matrix}$$
wherein
in the coordinates (x, y, z(x,y)), x denotes a coordinate with respect to the horizontal direction, y denotes a coordinate with respect to the vertical direction, z denotes a coordinate with respect to a height direction, and the horizontal, vertical, and height directions are perpendicular to one another.
